(19) United States
(12) Patent Application Publication
(10) Pub. No.: US 2014/0048313 A1
(43) Pub. Date: Feb. 20, 2014

(54) THERMALLY ENHANCED WIRING BOARD WITH THERMAL PAD AND ELECTRICAL POST

(71) Applicant: Bridge Semiconductor Corporation, Taipei City (TW)

(72) Inventors: Wei-Kuang PAN, Taipei City (TW); Charles W.C. LIN, Singapore (SG); Chia-Chung WANG, Hsinchu (TW)

(73) Assignee: Bridge Semiconductor Corporation, Taipei City (TW)

(21) Appl. No.: 13/962,248

(22) Filed: Aug. 8, 2013

Related U.S. Application Data
(63) Continuation-in-part of application No. 13/788,144, filed on Mar. 7, 2013.
Application No. 13/788,144 is a continuation-in-part of application No. 13/615,819, filed on Sep. 14, 2012.
Application No. 13/615,819 is a continuation-in-part of application No. 13/733,226, filed on Jan. 3, 2013.
Application No. 13/733,226 is a continuation-in-part of application No. 13/738,314, filed on Jan. 10, 2013.
(60) Provisional application No. 61/682,801, filed on Aug. 14, 2012.
(60) Provisional application No. 61/682,801, filed on Aug. 14, 2012.
(60) Provisional application No. 61/682,801, filed on Aug. 14, 2012.

(51) Int. Cl. H05K 1/02

(52) U.S. Cl. CPC H05K 1/0271
USPC 174/252

(57) ABSTRACT

A thermally enhanced wiring board with thermal pad and electrical post includes a metal slug, a metal pillar, a patterned interconnect substrate, an adhesive, a build-up circuitry and optionally a plated through hole. The metal slug and the metal pillar extend into apertures of the patterned interconnect substrate and are electrically connected to the build-up circuitry. The build-up circuitry covers the metal slug, the metal pillar and the patterned interconnect substrate and can provide signal routing. The metal slug can provide thermal contact surface, and the metal pillar can serve as power/ground plane or signal vertical transduction pathway.

### CROSS REFERENCE TO RELATED APPLICATION

This application is a continuation-in-part of U.S. application Ser. No. 13/788,144, entitled “THERMALLY ENHANCED WIRING BOARD WITH BUILT-IN HEAT SINK AND BUILD-UP CIRCUITRY” filed Mar. 7, 2013.

U.S. application Ser. No. 13/788,144 filed Mar. 7, 2013 is a continuation-in-part of U.S. application Ser. No. 13/615,819 filed Sep. 14, 2012, a continuation-in-part of U.S. application Ser. No. 13/733,226 filed Jan. 3, 2013 and a continuation-in-part of U.S. application Ser. No. 13/738,314 filed Jan. 10, 2013.

U.S. application Ser. No. 13/615,819 filed Sep. 14, 2012, U.S. application Ser. No. 13/733,226 filed Jan. 3, 2013 and U.S. application Ser. No. 13/738,314 filed Jan. 10, 2013 all claim the benefit of filing date of U.S. Provisional Application Ser. No. 61/682,801 filed Aug. 14, 2012.

### BACKGROUND OF THE INVENTION

1. Field of the Invention

The present invention relates to a thermally enhanced wiring board with thermal pad and electrical post, and more particularly to a thermally enhanced wiring board having a metal slug for thermal conduction and a metal pillar for electrical routing.

2. Description of Related Art

Semiconductor devices have high voltage, high frequency and high performance applications that require substantial power to perform the specified functions. As the power increases, the semiconductor device generates more heat. For portable electronics, the heat accumulation can be further aggravated by high packing density and small profile sizes which reduce the surface area to dissipate the heat. The heat not only degrades the chip, but also imposes thermal stress on the chip and the surrounding elements due to thermal expansion mismatch. As a result, the chip must be assembled to a thermal board so that the generated heat can be dissipated rapidly and efficiently from the chip to the board and to the ambient environment to ensure effective and reliable operation.

A good and effective design of thermal board typically requires heat conduction and heat spreading to a much larger surface area than the chip or a heat sink it is mounted on. In addition, thermal boards need to provide electrical routing and mechanical support for semiconductor devices. As such, thermal boards usually include a heat spreader or heat sink for heat removal, and an interconnect substrate for signal routing that includes pads for electrical connection to the semiconductor device and terminals for electrical connection to the next level assembly.

U.S. Pat. No. 6,507,102 to Juskey et al. discloses an assembly in which a composite substrate with fiberglass and cured thermosetting resin includes a central opening, a heat sink with a square or rectangular shape resembling the central opening is attached to the substrate at sidewalls of the central opening, top and bottom conductive layers are attached to the top and bottom of the substrate and electrically connected to one another by plated through-holes through the substrate, a chip is mounted on the heat sink and wire bonded to the top conductive layer, an encapsulant is molded on the chip and solder balls are placed on the bottom conductive layer. This structure allows the heat flows from the chip through the heat sink to the ambient environment. However, since the heat sink is barely adhered to the surrounded substrate from the sidewalls, fragile due to inadequate support and prone to crack during thermal cycling make this circuit board prohibitively unreliable for practical usage.

U.S. Pat. No. 6,528,882 to Ding et al. and U.S. Pat. No. 7,554,039 to Yokozuka et al. disclose a thermal enhanced ball grid array package in which the substrate includes a metal core layer. The chip is mounted on a die pad region at the top surface of the metal core layer, an insulating layer is formed on the bottom surface of the metal core layer, blind vias extend through the insulating layer to the metal core layer, thermal balls fill the blind vias and solder balls are placed on the substrate and aligned with the thermal balls. The heat from the chip flows through the metal core layer to the thermal balls to the PCB. However, since the metal core layer is a continuous plate, it limits the power delivery capability which requires a large conductive metal connecting the top and bottom patterned trace layers.

U.S. Pat. No. 7,038,311 to Woodall et al. and U.S. Pat. No. 8,310,067 to Zhao et al. disclose a thermal enhanced BGA package in which a heat sink with an inverted T-like shape is mounted on a window of a substrate to provide efficient heat dissipation from the chip through the pedestal to the expanded base to the PCB. Much like other drop-in heat sink types, the circuit board does not have any power delivery enhancement capability, and is fragile, unbalanced and may warp during assembly. This creates enormous concerns in reliability and low yield.

In addition, if semiconductor devices are susceptible to power shortage issues when they perform high frequency transmitting or receiving, the signal integrity of these devices can be adversely affected. In view of the various development stages and limitations in currently available wiring board for high power and high performance devices, providing a wiring board with adequate thermal dissipation, optimize signal integrity through solid conducting channels and maintain low cost manufacturing is highly desirable.

### SUMMARY OF THE INVENTION

The present invention has been developed in view of such a situation, and an object thereof is to provide a thermally enhanced wiring board with thermal pad and electrical post which can provide thermal conduction pathway and electrical routing for a semiconductor device attached thereon. The thermal pad and electrical post extend into apertures of a patterned interconnect substrate and further spread by a build-up circuitry. The patterned interconnect substrate can provide mechanical support and signal routing. The build-up circuitry is thermally connected to the thermal pad and is electrically connected to the electrical post by conductive vias. Also, the build-up circuitry can further be electrically connected to the patterned interconnect substrate by plated through holes or/and conductive vias. In summary, the thermal conduction pathway of the wiring board is provided by the thermal pad and the conductive via formed in the build-up circuitry that contacts the thermal pad directly. The electrical connection of the wiring board can be retained by the electrical post, the patterned interconnect substrate and the build-up circuitry for flexible signal routing or power delivery and return. Accordingly, the present invention provides a thermally enhanced wiring board that includes a patterned interconnect substrate, a metal slug, a metal pillar, an adhesive, a build-up circuitry and optionally a plated through hole.

The metal slug and the metal pillar respectively extend into first and second apertures of the patterned interconnect substrate and respectively serve as the thermal pad and the electrical post. In a preferred embodiment, the thermal pad and the electrical post are substantially coplanar with the patterned interconnect substrate in the second vertical direction. The thermal pad can have a surface exposed from the second vertical direction to provide a thermal conduction plane for semiconductor chip attachment. As a result, the generated heat can be dissipated rapidly and efficiently from the chip to the board and to the ambient environment to ensure effective and reliable operation. The thermal pad can also serve as a power or ground plane to provide power delivery or ground return paths. Further, the electrical post may be a power/ground post or signal post and can include an interconnect pad exposed from the second vertical direction for electrical connection. The thermal pad and the electrical post can be made of copper or aluminum, and preferably have a thickness range between 25 microns and 2 mm, more preferably between 100 microns and 1 mm, and most preferably between 200 microns and 500 microns. According to actual demand, plural thermal pads and electrical posts may be built-in the wiring board. For instance, the wiring board may include multiple metal slugs as thermal pads and multiple metal pillars respectively as power/ground posts and signal posts. The metal slug and metal pillars for the use of power and ground planes can effectively shorten the power delivery and ground return paths and therefore reduce resistance and parasitic capacitance. Further, the metal slugs and the metal pillars allow a flexible design by adjusting numbers of power and ground planes, their thickness, shapes and locations. For instance, the metal slug can have a square or rectangular periphery with a dimension of about 5×5 mm to 10×10 mm, and the metal pillar can have a cylindrical shape with a diameter of about 0.5 mm to 1 mm.

The patterned interconnect substrate can include patterned wiring layer on one or both surfaces thereof for electrical routing. For instance, the patterned interconnect substrate can include a first patterned wiring layer on its first surface that faces the first vertical direction and a second patterned wiring layer on its second surface that faces the second vertical direction. The first and second patterned wiring layers can be electrically connected to one another by one or more plated through holes that extend through the patterned interconnect substrate or by connecting elements built-in the patterned interconnect substrate, such as conductive through-via and embedded conductive layer. The patterned interconnect substrate can extend to peripheral edges of the wiring board and provide mechanical support to suppress warp and bend of the wiring board. The patterned interconnect substrate can be made of organic materials such as epoxy, polyimide or copper-clad laminate. The patterned interconnect substrate can also be made of ceramics or other various inorganic materials, such as aluminum oxide (Al₂O₃), aluminum nitride (AlN), silicon nitride (SiN), silicon (Si), glass, etc.

The adhesive covers the patterned interconnect substrate in the first vertical direction and can extend laterally from the metal slug and the metal pillar to peripheral edges of the wiring board. Moreover, the adhesive can extend into gaps between the metal slug and the patterned interconnect substrate and between the metal pillar and the patterned interconnect substrate in the second vertical direction. As a result, the adhesive can laterally cover and surround and conformally coat and contact the peripheral edges of the metal slug and the metal pillar and the aperture inner walls of the patterned interconnect substrate. In a preferred embodiment, the adhesive is substantially coplanar with the metal slug, the metal pillar and the patterned interconnect substrate in the second vertical direction, and is coplanar with the metal slug and the metal pillar in the first vertical direction. The adhesive can have a first thickness (in the first/second vertical directions) where it is adjacent to the first surface of the patterned interconnect substrate and a second thickness (in the lateral directions orthogonal to the first/second vertical directions) in the gaps that is different from the first thickness. Further, the wiring board of the present invention can include a patterned metal layer that extend from the adhesive in the second vertical direction and electrically couples the thermal pad and the patterned interconnect substrate and the electrical post and the patterned interconnect substrate respectively. Preferably, the patterned metal layer is coplanar with the patterned interconnect substrate, the thermal pad and the electrical post in the second vertical direction.

The build-up circuitry covers the metal slug, the metal pillar and the adhesive in the first vertical direction. The build-up circuitry can include a first dielectric layer, first via openings and one or more first conductive traces. For instance, the first dielectric layer covers and contacts the metal slug, the metal pillar and the adhesive in the first vertical direction and can extend to peripheral edges of the wiring board, and the first conductive traces extend from the first dielectric layer in the first vertical direction.

The first via openings in the first dielectric layer are aligned with the metal slug and the metal pillar and optionally aligned with the patterned interconnect substrate. For instance, the first via openings aligned with the metal slug and the metal pillar can extend through the first dielectric layer and are adjacent to the metal slug and the metal pillar, while the first via opening aligned with the patterned interconnect substrate can extend through the first dielectric layer and the adhesive and is adjacent to the patterned interconnect substrate. One or more first conductive traces extend from the first dielectric layer in the first vertical direction, extend laterally on the first dielectric layer, and extend through the first via openings in the second vertical direction to form first conductive vias that can provide thermal connection for the metal slug and electrical connection for the metal pillar and the patterned interconnect substrate. Specifically, the first conductive traces can directly contact the metal slug, the metal pillar and optionally the patterned interconnect substrate. As a result, the thermal conduction pathway between the metal slug and the build-up circuitry and the electrical connection between the build-up circuitry and the metal pillar, between the build-up circuitry and the metal post, and between the build-up circuitry and the patterned interconnect substrate can be established without using other materials such as solder. The thermal conduction pathway of the wiring board can be provided by the metal slug and the first conductive vias. The power delivery and ground return paths of the wiring board can be provided by the metal pillars as well as the metal slug and the first conductive traces to minimize the voltage drop caused by plated through holes.

The build-up circuitry can include additional layers of dielectric, additional layers of via openings, and additional layers of conductive traces if needed for further signal routing. The outmost conductive traces of the build-up circuitry can respectively include one or more terminal pads to provide electrical contacts for an electronic device such as a semiconductor chip, a plastic package or another semiconductor assembly. The terminal pads can include an exposed contact surface that faces in the first vertical direction. As a result, the wiring board can include electrical contacts (i.e. the interconnect pads of the patterned interconnect substrate and the terminal pads of the build-up circuitry) that are electrically connected to one another and located on opposite surfaces that face in opposite vertical directions, so that the wiring board is stackable and electronic devices can be electrically connected to the wiring board using a wide variety of connection media including wire bonding or solder bumps as the electrical contacts.

The plated through hole can extend vertically through the adhesive to provide an electrical connection between the patterned interconnect substrate and the build-up circuitry. For instance, the plated though hole at a first end can extend to and be electrically connected to an outer or inner conductive layer of the build-up circuitry, and at a second end can extend to and be electrically connected to the second patterned wiring layer of the patterned interconnect substrate so as to provide signal routing in the vertical direction between the build-up circuitry and the patterned interconnect substrate.

The present invention further provides a semiconductor assembly in which a semiconductor device such as chip is mounted on the thermal pad and is electrically connected to the patterned interconnect substrate and the electrical post. The semiconductor device can be mounted on the thermal pad using various thermally conductive materials, such as thermal adhesive or solder, and electrically connected to the patterned interconnect substrate and the electrical post using a wide variety of connection media including solder bumps, gold wires. As a result, the thermal performance of the assembly can be enhanced by the thermal conduction pathway provided by the thermal pad and the first conductive traces that directly contact the thermal pad. The voltage drop can be minimized by the power delivery and ground return paths provided by the electrical posts as power/ground planes and the first conductive traces that directly contact the electrical posts.

The present invention has numerous advantages. The built-in thermal pad can provide a thermal contact plane for semiconductor chip attachment and can also further serve as ground/power plane. The built-in electrical post can serve as signal vertical transduction pathway or ground/power plane to effectively shorten the power delivery and ground return paths and therefore reduce resistance and parasitic capacitance. The patterned interconnect substrate can provide mechanical support and be electrically connected to the build-up circuitry by a plated through hole or/and conductive vias in the build-up circuitry that directly contact the patterned interconnect substrate to provide signal routing. The conductive vias in the build-up circuitry can provide direct thermal connection between the thermal pad and the build-up circuitry and are advantageous for a high thermal conduction pathway. Also, the conductive vias in the build-up circuitry can further provide electrical connection for the electrical posts, and thus the power delivery and return pathway can be provided by conductive vias and electrical posts so as to avoid significant voltage drop caused by plated through holes. The signal routing can be provided by the build-up circuitry and the patterned interconnect substrate as well as the electrical post as the signal post and is advantageous for high I/O and high performance applications due to the high routing capability of the build-up circuitry. The adhesive can provide a robust mechanical bond between the thermal pad and the patterned interconnect substrate, between the electrical post and the patterned interconnect substrate and between the build-up circuitry and the patterned interconnect substrate, thereby enhancing reliability of the wiring board. The wiring board and the semiconductor assembly using the same are reliable, inexpensive and well-suited for high volume manufacture.

These and other features and advantages of the present invention will be further described and more readily apparent from a review of the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1-7 are cross-sectional views showing a method of making a thermally enhanced wiring board that includes a patterned interconnect substrate, a thermal pad, multiple electrical posts, an adhesive, a build-up circuitry and plated through holes in accordance with an embodiment of the present invention, in which FIGS. 2A and 3A are top perspective views corresponding to FIGS. 2 and 3, respectively, and FIG. 3B is a bottom perspective view of the patterned interconnect substrate;

FIGS. 8 and 8A are cross-section and simplified partial top views, respectively, of a semiconductor assembly that includes a semiconductor device attached to the thermal pad of the wiring board in accordance with an embodiment of the present invention;

FIGS. 9A and 9B are top and bottom perspective views, respectively, of another thermally enhanced wiring board with plated through holes exposed from peripheral edges in accordance with another embodiment of the present invention; and

FIG. 10 is a cross-sectional view of yet another thermally enhanced wiring board with first conductive traces in contact with the patterned interconnect substrate in accordance with yet another embodiment of the present invention.

### DETAILED DESCRIPTION OF THE PREFERRED EMBODIMENT

Hereafter, examples will be provided to illustrate the embodiments of the present invention. Other advantages and effects of the invention will become more apparent from the disclosure of the present invention. It should be noted that these accompanying figures are simplified. The quantity, shape and size of components shown in the figures may be modified according to practically conditions, and the arrangement of components may be more complex. Other various aspects also may be practiced or applied in the invention, and various modifications and variations can be made without departing from the spirit of the invention based on various concepts and applications.

### Embodiment 1

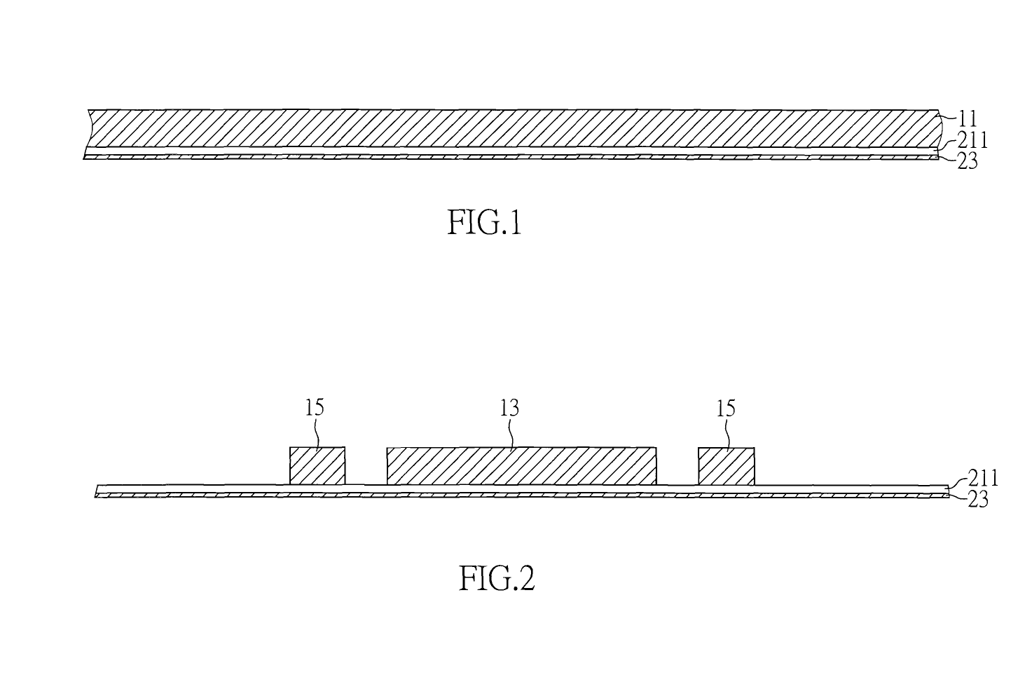

FIGS. 1-7 are cross-sectional views showing a method of making a thermally enhanced wiring board that includes a patterned interconnect substrate, a thermal pad, multiple electrical posts, an adhesive, a build-up circuitry and plated through holes in accordance with an embodiment of the present invention.

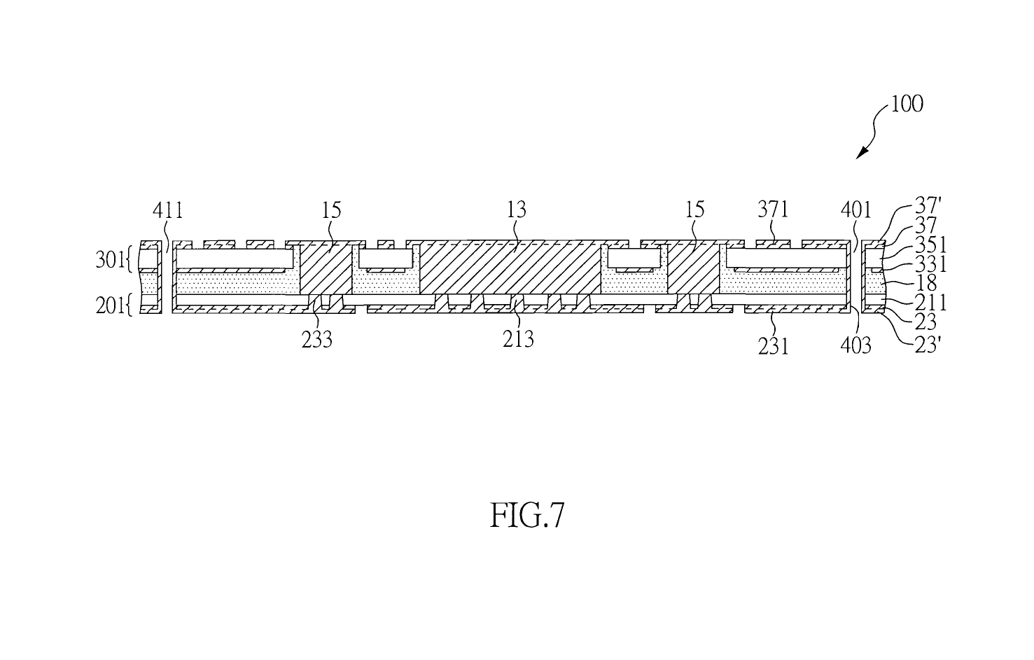

As shown in FIG. 7, thermally enhanced wiring board 100 includes metal slug 13, metal pillars 15, adhesive 18, build-up circuitry 201, patterned interconnect substrate 301 and plated through holes 411. Metal slug 13 and metal pillars 15 extend into apertures of patterned interconnect substrate 301 and respectively serve as thermal pad and electrical posts. Adhesive 18 is sandwiched between and provides secure robust mechanical bonds between metal slug 13 and patterned interconnect substrate 301, between metal pillars 15 and patterned interconnect substrate 301, and between build-up circuitry 201 and patterned interconnect substrate 301. Build-up circuitries 201 covers metal slug 13, metal pillars 15 and adhesive 18 in the downward direction and is electrically connected to metal slug 13 and metal pillars 15 through first conductive vias 233 so as to provide thermal conduction pathway and power delivery and return paths. Plated through holes 411 extend through patterned interconnect substrate 301, adhesive 18 and build-up circuitry 201 and can provide signal transduction pathway between build-up circuitry 201 and patterned interconnect substrate 301.

FIG. 1 is a cross-sectional view of a laminate substrate that includes metal sheet 11, first dielectric layer 211 and first metal layer 23. First metal sheet 11 covers first dielectric layer 211 in the upward direction and is illustrated as an un-patterned copper sheet with a thickness of 0.3 mm. First metal layer 23 covers first dielectric layer 211 in the downward direction and is illustrated as an un-patterned copper layer with a thickness of 17 microns. First dielectric layer 211, such as epoxy resin, glass-epoxy, polyimide and the like, is sandwiched between metal sheet 11 and first metal layer 23 and typically has a thickness of 50 microns.

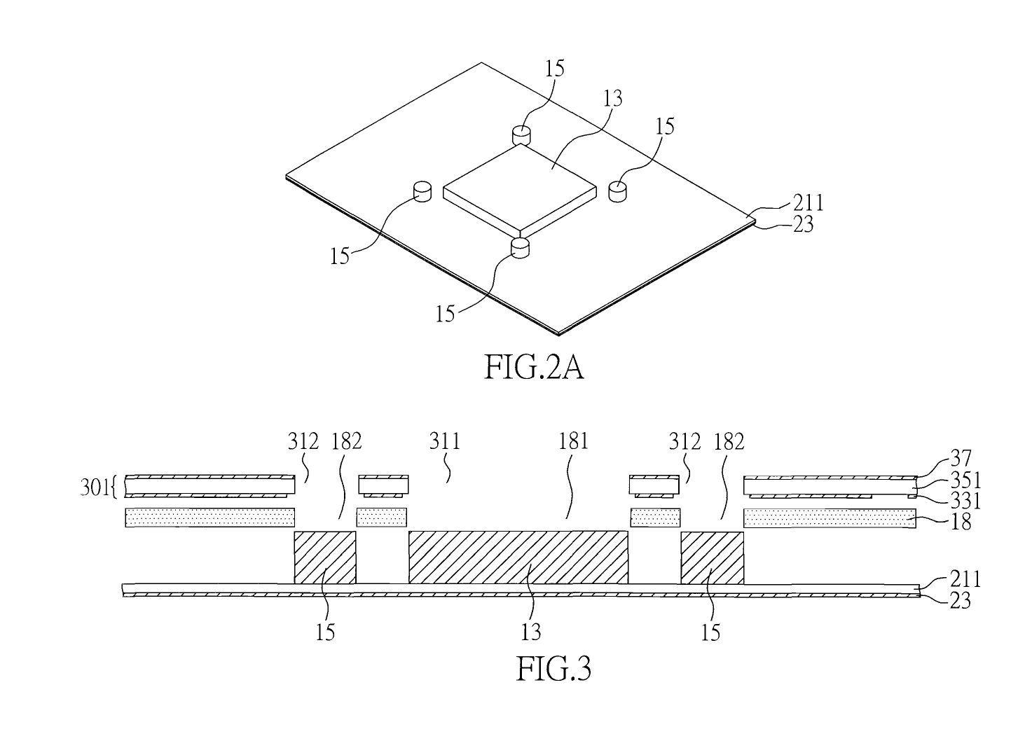

FIGS. 2 and 2A are cross-sectional and top perspective views, respectively, of the structure with metal slug 13 and metal pillars 15 defined on first dielectric layer 211. Selected portions of metal sheet 11 can be removed using photolithography and wet etching to define the remaining portions of metal sheet 11 as metal slug 13 and metal pillars 15. In this embodiment, metal slug 13 is illustrated as a rectangular copper slug with a dimension of 3 mm by 3 mm, and metal pillars 15 are illustrated as copper cylinders with a diameter of 0.5 mm.

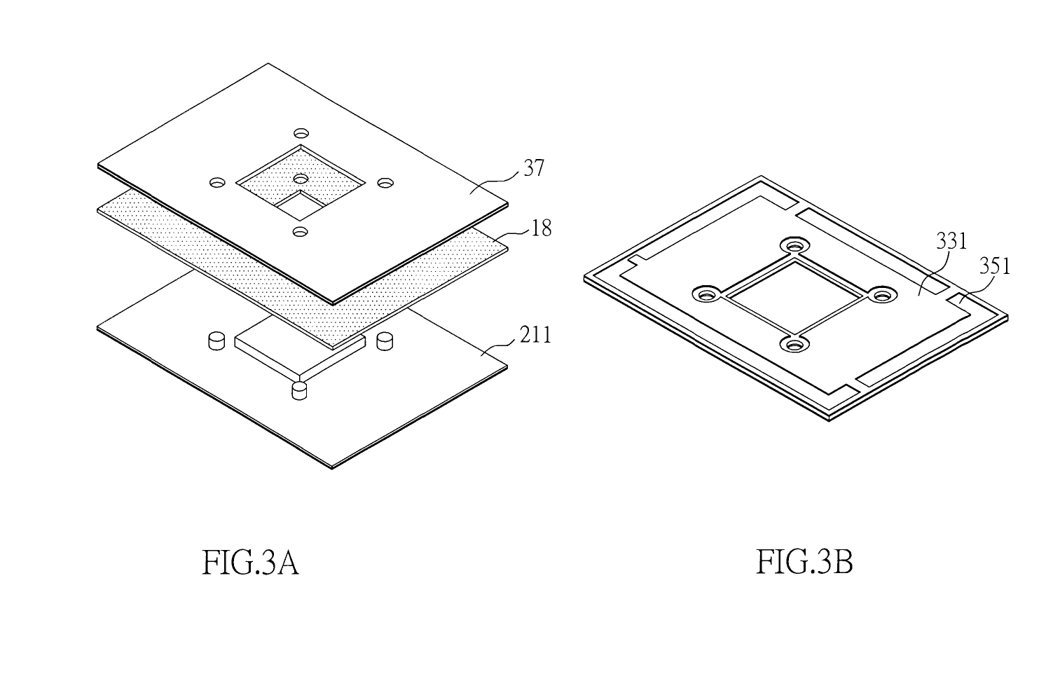

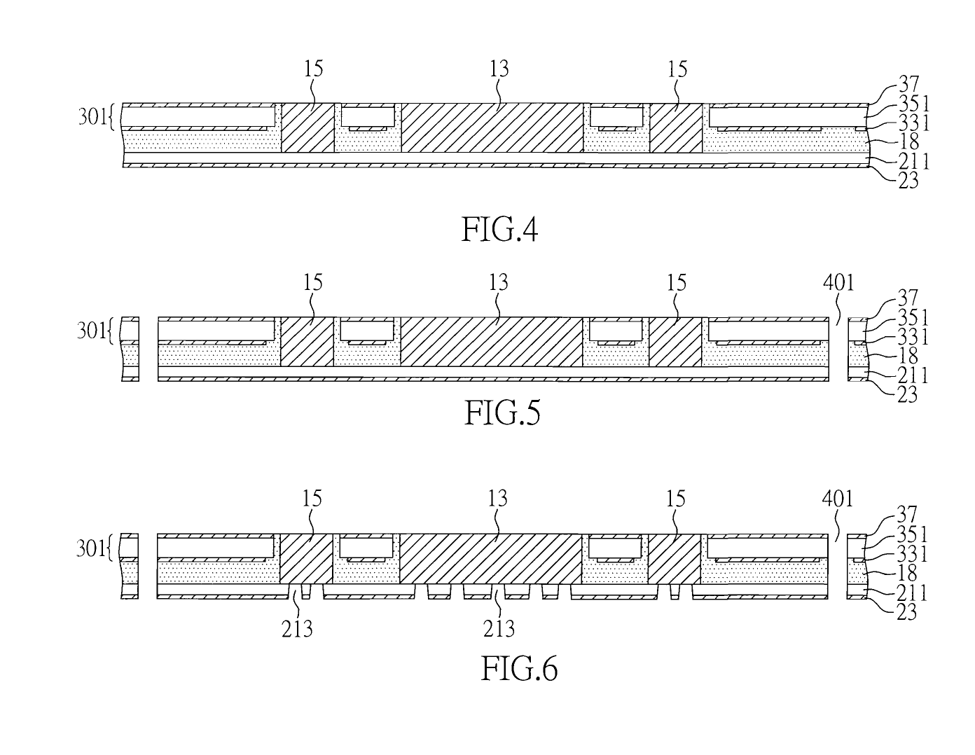

FIGS. 3 and 4 are cross-sectional views showing a process of laminating patterned interconnect substrate 301 onto first dielectric layer 211 using adhesive 18, FIG. 3A is a top perspective view corresponding to FIG. 3, and FIG. 3B is a bottom perspective view of the patterned interconnect substrate 301. The lamination process is executed by inserting metal slug 13 into first aperture 311 of patterned interconnect substrate 301 as well as first opening 181 of adhesive 18, and inserting metal pillars 15 into second apertures 312 of patterned interconnect substrate 301 as well as second openings 182 of adhesive 18. Patterned interconnect substrate 301 is illustrated as a laminate that includes first patterned wiring layer 331, insulating layer 351 and second metal layer 37, and is mounted onto first dielectric layer 211 with first patterned wiring layer 331 facing first dielectric layer 211. Insulating layer 351 is illustrated as a Rogers core with a thickness of 0.1 mm, and also can be various organic or inorganic electrical insulators. First patterned wiring layer 331 extends from insulating layer 351 in the downward direction and is illustrated as a patterned copper layer with a thickness of 35 microns. Second metal layer 37 extends from insulating layer 351 in the upward direction and is illustrated as an un-patterned copper layer with a thickness of 35 microns. Adhesive 18 is illustrated as Rogers prepreg with a thickness of 0.1 mm, and also can be various dielectric films or prepregs formed from numerous organic or inorganic electrical insulators. First and second apertures 311, 312 are formed by laser cutting through patterned interconnect substrate 301 and can be formed with other techniques such as punching and mechanical drilling. Likewise, first and second openings 181, 182 are formed by laser cutting through adhesive 18 and can be formed with other techniques such as punching and mechanical drilling.

Under heat and pressure, adhesive 18 between patterned interconnect substrate 301 and first dielectric layer 211 is melt and forced into gaps between metal slug 13 and patterned interconnect substrate 301 and between metal pillars 15 and patterned interconnect substrate 301. Metal slug 13 and metal pillars 15 are spaced from patterned interconnect substrate 301 by adhesive 18 and are coplanar with patterned interconnect substrate 301 in the upward direction. Adhesive 18 as solidified provides secure robust mechanical bonds between metal slug 13 and patterned interconnect substrate 301, between metal pillars 15 and patterned interconnect substrate 301, and between first dielectric layer 211 and patterned interconnect substrate 301, and is coplanar with metal slug 13, metal pillars 15 and patterned interconnect substrate 301 in the upward direction.

FIG. 5 is a cross-sectional view of the structure provided with through holes 401. Through holes 401 extend through first metal layer 23, first dielectric layer 211, adhesive 18 and patterned interconnect substrate 301 in the vertical direction. Through holes 401 are formed by mechanical drilling and can be formed by other techniques such as laser drilling and plasma etching with or without wet etching.

FIG. 6 is a cross-sectional view of the structure provided with first via openings 213. First via openings 213 extend through first metal layer 23 and first dielectric layer 211 to expose selected portions of metal slug 13 and metal pillars 15 in the downward direction. First via openings 213 may be formed by numerous techniques including laser drilling, plasma etching and photolithography, and typically have a diameter of 50 microns. Laser drilling can be enhanced by a pulsed laser. Alternatively, a scanning laser beam with a metal mask can be used. For instance, copper can be etched first to create a metal window followed by laser.

Referring now to FIG. 7, first conductive traces 231 are formed on first dielectric layer 211 by depositing first plated layer 23′ on first metal layer 23 and into first via openings 213 and then patterning first metal layer 23 and first plated layer 23′ thereon. Alternatively, in some embodiments which apply a laminate substrate without first metal layer 23, the first dielectric layer 211 can be directly metallized to form first conductive traces 231. Meanwhile, second patterned wiring layer 371 are formed on insulating layer 351 by depositing second plated layer 37′ on second metal layer 37 and then patterning second metal layer 37 and second plated layer 37′ thereon.

Also shown in FIG. 7 are second plated layer 37′ further deposited on adhesive 18, metal slug 13 and metal pillars 15 and connecting layer 403 deposited in through holes 401 to provide plated through holes 411. Second plated layer 37′ deposited on adhesive 18 is a patterned metal layer that electrically couples the thickened metal slug 13 and second patterned wiring layer 371 and the thickened metal pillars 15 and second patterned wiring layer 371. Connecting layer 403 is a hollow tube that covers the sidewall of through holes 401 in lateral directions and extends vertically to electrically connect first metal layer 23 as well as first plated layer 23′ thereon to second metal layer 37 as well as second plated layer 37′ thereon, and an insulative filler can optionally fill the remaining space in through holes 401. Alternatively, connecting layer 403 can fill through hole 401 in which case plated through hole 411 is a metal post and there is no space for an insulative filler in through holes 401.

Preferably, first plated layer 23′, second plated layer 37′ and connecting layer 403 are the same material deposited simultaneously in the same manner and have the same thickness. First plated layer 23′, second plated layer 37′ and connecting layer 403 can be deposited by numerous techniques including electroplating, electroless plating, evaporating, sputtering, and their combinations as a single layer or multiple layers. For instance, they are deposited by first dipping the structure in an activator solution to render the dielectric layer catalytic to electroless copper, and then a thin copper layer is electrolessly plated to serve as the seeding layer before a second copper layer is electroplated on the seeding layer to a desirable thickness. Alternatively, the seeding layer can be formed by sputtering a thin film such as titanium/copper before depositing the electroplated copper layer on the seeding layer. Once the desired thickness is achieved, plated layers can be patterned to form first conductive traces 231 and second patterned wiring layer 371 by numerous techniques including wet etching, electro-chemical etching, laser-assist etching, and their combinations with an etch mask (not shown) thereon that defines first conductive traces 231 and second patterned wiring layer 371, respectively.

First metal layer 23, second metal layer 37, first plated layer 23′, second plated layer 37′, connecting layer 403, metal slug 13 and metal pillars 15 are shown as a single layer for convenience of illustration. The boundary (shown in phantom) between the metal layers may be difficult or impossible to detect since copper is plated on copper. However, the boundaries between first plated layer 23′ and first dielectric layer 211, between second plated layer 37′ and adhesive 18, between connecting layer 403 and first dielectric layer 211, between connecting layer 403 and adhesive 18, and between connecting layer 403 and insulating layer 351 are clear.

Accordingly, as shown in FIG. 7, thermally enhanced wiring board 100 is accomplished and includes metal slug 13, metal pillars 15, adhesive 18, build-up circuitry 201, patterned interconnect substrate 301, and plated through holes 411. In this illustration, build-up circuitry 201 includes first dielectric layer 211 and first conductive traces 231, while patterned interconnect substrate 301 includes first patterned wiring layer 331, insulating layer 351 and second patterned wiring layer 371. Metal slug 13 and metal pillars 15 extend into first and second apertures 311, 312 of patterned interconnect substrate 301 and are coplanar with patterned interconnect substrate 301 and second plated layer 37′ on adhesive 18 in the upward direction and are coplanar with adhesive 18 in the downward direction. Metal slug 13 can serves as a thermal pad to provide thermal conduction pathway for semiconductor chips attached thereon and can also serve as a ground/power plane. In this illustration, metal slug 13 serve as both thermal pad and ground plane. Metal pillars 15 can serve as electrical posts for signal routing or power/ground connection. For instance, metal pillars 15 can include signal pillars, power pillars and ground pillars. In this illustration, metal pillars 15 serve as power posts to provide power planes. First conductive traces 231 extend from first dielectric layer 211 in the downward direction, extend laterally on first dielectric layer 211 and extend into first via openings 213 in the upward direction to form first conductive vias 233 in direct contact with metal slug 13 and metal pillars 15, thereby providing thermal conduction for metal slug 13 and electrical routing for metal pillars 15. As a result, the thermal conduction pathway of the wiring board 100 is provided by metal slug 13 and first conductive vias 233 formed in build-up circuitry 201 that contact metal slug 13 directly, and the power delivery and ground return paths can be provided by metal slug 13, metal pillars 15 and first conductive vias 233 formed in build-up circuitry 201 that contact metal slug 13 and metal pillars 15 directly. Plated through holes 411 are essentially shared by patterned interconnect substrate 301, adhesive 18 and build-up circuitry 201, and extend through first dielectric layer 211, adhesive 18 and insulating layer 351 in the vertical directions to provide electrical connection between first conductive traces 231 and second patterned wiring layer 371 for signal routing.

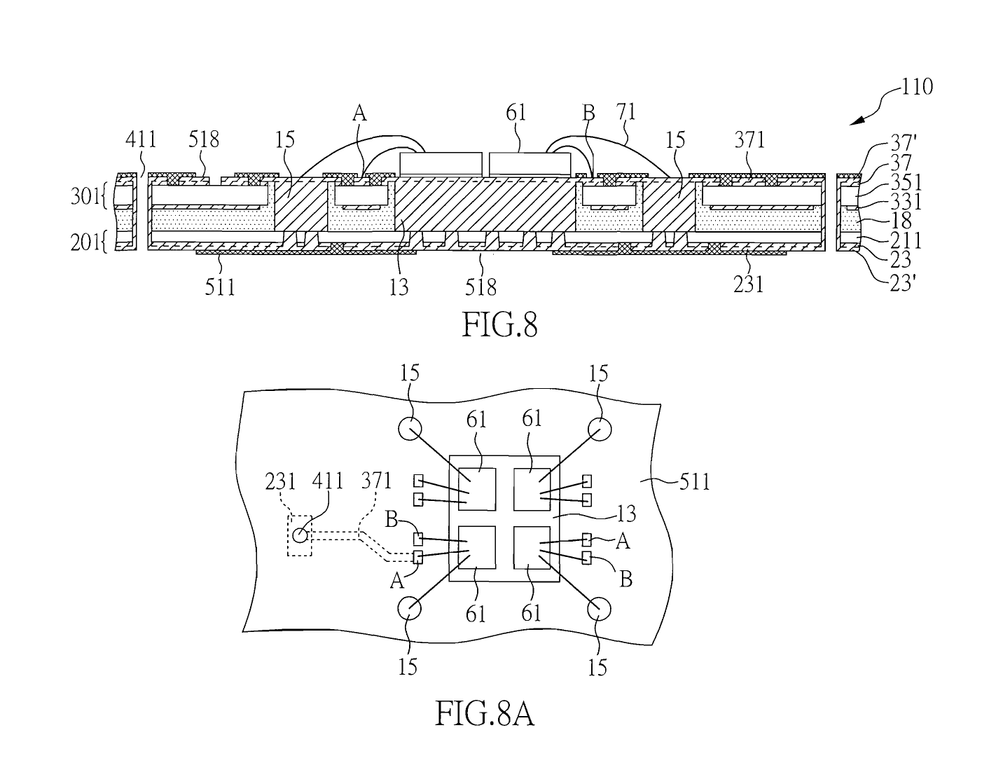

FIG. 8 is a cross-sectional view of semiconductor assembly 110 in which semiconductor devices 61 are soldered onto the exposed surface of metal slug 13 and are electrically connected to patterned interconnect substrate 301 and metal pillars 15 via wire bonds 71, and FIG. 8A is a simplified partial top view corresponding to FIG. 8. In this illustration, the signal contact pad of semiconductor device 61 is wire bonded to the selected portion A of second patterned wiring layer 371 that is electrically connected to build-up circuitry 201 through plated through hole 411 for signal routing; the ground contact pad of semiconductor device 61 is wire bonded to the selected portion B of second patterned wiring layer 371 that is electrically connected to metal slug 13 by the metal layer that extends from adhesive 18 in the upward direction and electrically couples metal slug 13 and second patterned wiring layer 371 for ground connection; and the power contact pad of semiconductor device 61 is wire bonded to exposed portions of metal pillar 15 for power connection.

Also shown in FIG. 8 is solder mask material 511 over build-up circuitry 201 and patterned interconnect substrate 301. Selected portions of metal slug 13, metal pillars 15, first conductive traces 231 and second patterned wiring layer 371 are exposed from solder mask openings 518. The exposed portions of first conductive traces 231 can accommodate connection media including solder balls and be further electrically connected with another assembly or external components.

### Embodiment 2

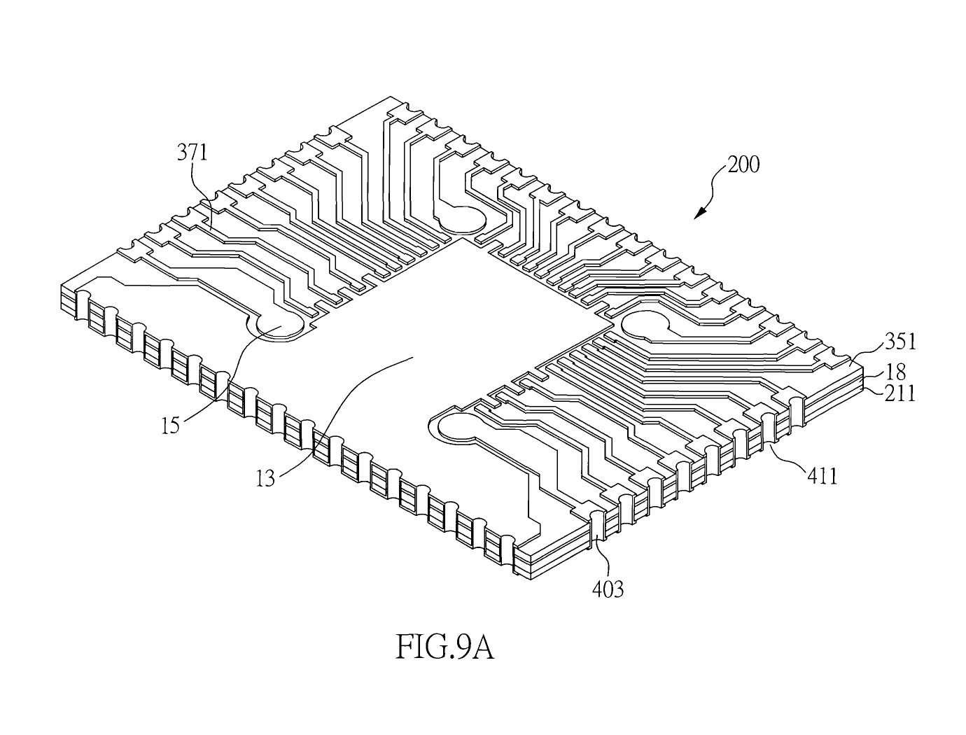

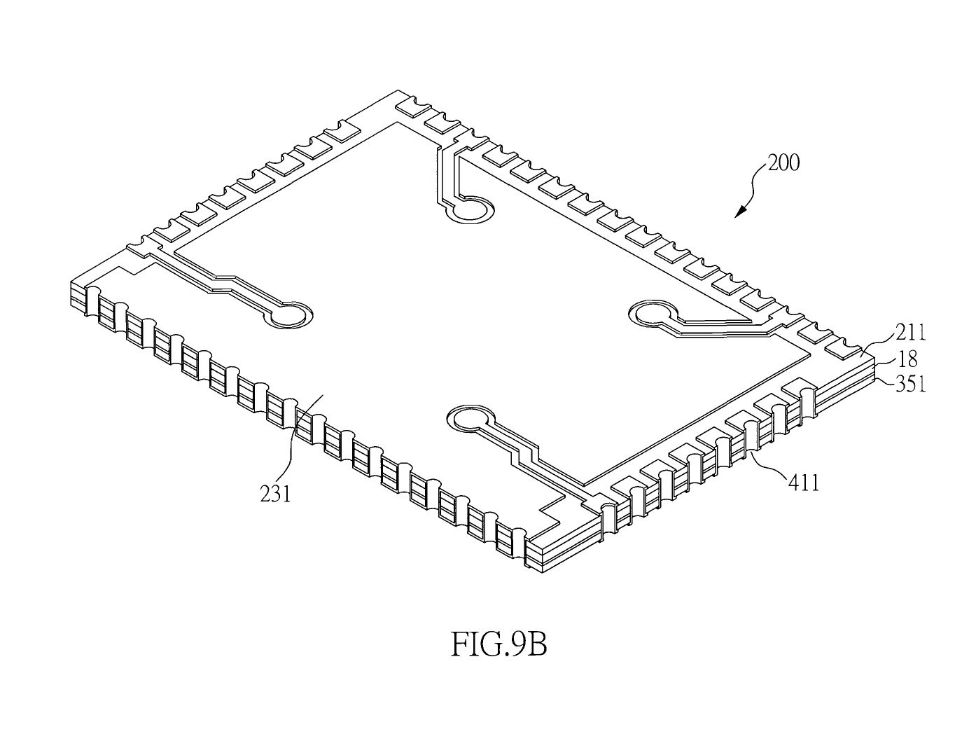

FIGS. 9A and 9B are top and bottom perspective views, respectively, of thermally enhanced wiring board 200 with plated through holes 411 exposed from peripheral edges in accordance with another embodiment of the present invention.

In this embodiment, wiring board 200 is manufactured in a manner similar to that illustrated in Embodiment 1, except that a cutting process is further executed along a cutting line that intersects plated through holes 411. As a result, plated through holes 411 has a semi-tubular shape with a semi-circular circumference rather than a tubular shape with a circular circumference. The exposed connecting layer 403 of plated through holes 411 can serve as electrical contact surface.

### Embodiment 3

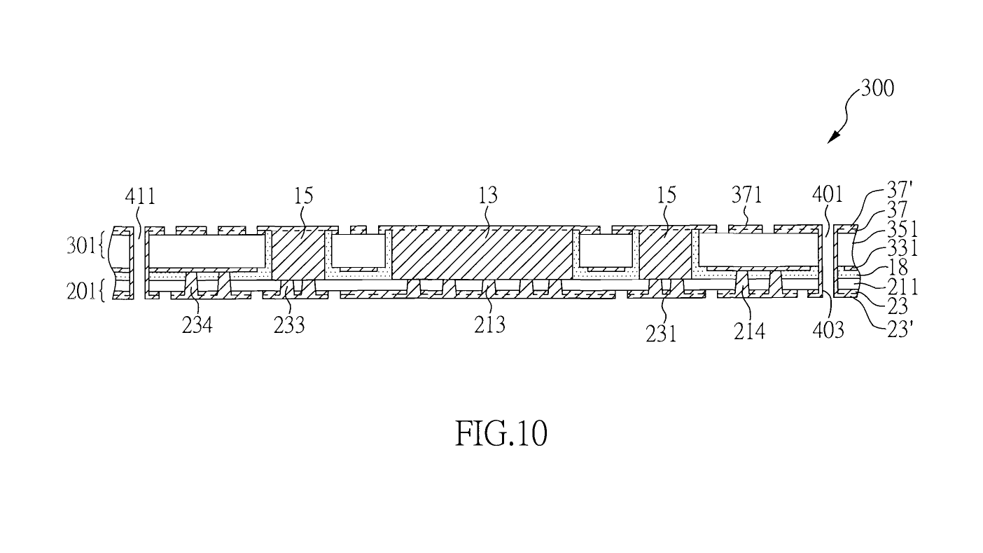

FIG. 10 is a cross-sectional view of thermally enhanced wiring board 300 with first conductive traces 231 in contact with patterned interconnect substrate 301 in accordance with yet another embodiment of the present invention.

In this embodiment, wiring board 300 is manufactured in a manner similar to that illustrated in Embodiment 1, except that first conductive traces 231 further extend into additional first via openings 214 through first dielectric layer 211 and adhesive 18 to form additional first conductive vias 234 in direct contact with first patterned wiring layer 331 of patterned interconnect substrate 301. As a result, patterned interconnect substrate 301 are electrically connected to build-up circuitry 201 by plated through holes 411 and first conductive vias 234 in contact with first patterned wiring layer 331 that can be electrically connected to second patterned wiring layer 371 by embedded connecting elements (not shown in figure) of patterned interconnect substrate 301.

The thermally enhanced wiring boards and semiconductor assemblies described above are merely exemplary. Numerous other embodiments are contemplated. In addition, the embodiments described above can be mixed-and-matched with one another and with other embodiments depending on design and reliability considerations. For instance, the patterned interconnect substrate can include ceramic material or epoxy-based laminate, and can have embedded single-level conductive traces or multi-level conductive traces. The patterned interconnect substrate can include additional first and second apertures to accommodate additional metal slugs and metal pillars, and the build-up circuitry can include additional conductive vias to accommodate additional metal slugs and metal pillars.

As shown in the above embodiments, a semiconductor device can share or not share the metal slug with other semiconductor devices. For instance, a single semiconductor device can be mounted on the metal slug. Alternatively, numerous semiconductor devices can be mounted on the metal slug. For instance, four small chips in a 2×2 array can be attached to the metal slug and the patterned interconnect substrate can include additional interconnect pads to receive and route additional chip pads. This may be more cost effective than providing a metal slug for each chip.

The semiconductor device can be a packaged or unpackaged chip. Furthermore, the semiconductor device can be a bare chip, or a wafer level packaged die, etc. A semiconductor device can be mechanically and thermally connected to the metal slug and electrically connected to the patterned interconnect substrate using bonding wires. The metal slug can be customized for the semiconductor device. For instance, the metal slug can have a square or rectangular shape at its exposed surface with the same or similar topography as the thermal contact of the semiconductor device.

The term “adjacent” refers to elements that are integral (single-piece) or in contact (not spaced or separated from) with one another. For instance, the first conductive trace is adjacent to the metal slug and metal pillar but not the second patterned wiring layer of the patterned interconnect substrate.

The term “overlap” refers to above and extending within a periphery of an underlying element. Overlap includes extending inside and outside the periphery or residing within the periphery. For instance, in the position that the build-up circuitry faces the upward direction, the build-up circuitry overlaps the patterned interconnect substrate since an imaginary vertical line intersects the build-up circuitry and the patterned interconnect substrate, regardless of whether another element such as the adhesive is between the build-up circuitry and the patterned interconnect substrate and is intersected by the line, and regardless of whether another imaginary vertical line intersects the build-up circuitry but not the patterned interconnect substrate (within the apertures of the patterned interconnect substrate). Likewise, the build-up circuitry overlaps the metal slug and the metal pillar, and the metal slug and the metal pillar are overlapped by the build-up circuitry. Moreover, overlap is synonymous with over and overlapped by is synonymous with under or beneath.

The term “contact” refers to direct contact. For instance, the first conductive trace contacts the metal slug and the metal pillar but not the second patterned wiring layer of the patterned interconnect substrate.

The term “cover” refers to incomplete and complete coverage in a vertical and/or lateral direction. For instance, in the position that the build-up circuitry faces the downward direction, the adhesive covers the patterned interconnect substrate in the downward direction and laterally covers the metal slug and the metal pillar, but does not cover the metal slug and the metal pillar in the upward and downward directions. Likewise, the build-up circuitry covers the patterned interconnect substrate in the downward direction regardless of whether another element such as the adhesive is between the patterned interconnect substrate and the build-up circuitry.

The term “layer” refers to patterned and un-patterned layers. For instance, the first metal layer disposed on the first dielectric layer can be an un-patterned blanket sheet before photolithography and wet etching. Furthermore, a layer can include stacked layers.

The terms “opening”, “aperture”, “through hole” and “through via” refer to a through hole and are synonymous. For instance, in the position that the build-up circuitry faces the downward direction, the metal slug and the metal pillar are exposed by the patterned interconnect substrate in the upward direction when they are inserted into the apertures in the patterned interconnect substrate.

The term “inserted” refers to relative motion between elements. For instance, the metal slug and the metal pillar are inserted into the apertures regardless of whether the patterned interconnect substrate is stationary and the metal slug and the metal pillar move towards the patterned interconnect substrate, the metal slug and the metal pillar are stationary and the patterned interconnect substrate moves towards the metal slug and the metal pillar or the metal slug/pillar and the patterned interconnect substrate both approach the other. Furthermore, the metal slug and the metal pillar are inserted (or extend) into the apertures regardless of whether they go through (enter and exit) or do not go through (enter without exiting) the apertures.

The phrase “aligned with” refers to relative position between elements regardless of whether elements are spaced from or adjacent to one another or one element is inserted into and extends into the other element. For instance, the first via opening are aligned with the metal slug and the metal pillar, and the metal slug and the metal pillar are aligned with the apertures.

The phrases “mounted on”, “mounted onto”, “attached onto” and “laminating . . . onto” include contact and non-contact with a single or multiple support element(s). For instance, the semiconductor device is mounted on the metal slug regardless of whether it contacts the metal slug or is separated from the metal slug by a solder.

The phrase “adhesive . . . in the gaps” refers to the adhesive in the gaps. For instance, the adhesive can have a second thickness in the gaps that is different from the first thickness refers to the adhesive in the gaps can have a second thickness that is different from the first thickness.

The phrases “electrical connection” or “electrically connects” or “electrically connected” refers to direct and indirect electrical connection. For instance, the first conductive trace can provide an electrical connection between the terminal pad and the patterned interconnect substrate regardless of whether the first conductive trace is adjacent to the terminal pad or electrically connected to the terminal pad by additional conductive traces of the build-up circuitry.

The term “above” refers to upward extension and includes adjacent and non-adjacent elements as well as overlapping and non-overlapping elements. For instance, in the position that the build-up circuitry faces the downward direction, the metal slug and the metal pillar extend above, are adjacent to and protrude from the first dielectric layer.

The term “below” refers to downward extension and includes adjacent and non-adjacent elements as well as overlapping and non-overlapping elements. For instance, in the position that the build-up circuitry faces the downward direction, the build-up circuitry extends below the patterned interconnect substrate in the downward direction regardless of whether the build-up circuitry is adjacent to the patterned interconnect substrate.

The “first vertical direction” and “second vertical direction” do not depend on the orientation of the wiring board, as will be readily apparent to those skilled in the art. For instance, the build-up circuitry faces the first vertical direction and the patterned interconnect substrate faces the second vertical direction regardless of whether the wiring board is inverted. Likewise, the first dielectric layer can extend “laterally” to peripheral edges of the wiring board in a lateral plane regardless of whether the wiring board is inverted, rotated or slanted. Furthermore, the first vertical direction is the downward direction and the second vertical direction is the upward direction in the position that the build-up circuitry faces the downward direction, and the first vertical direction is the upward direction and the second vertical direction is the downward direction in the position that the build-up circuitry faces the upward direction.

The thermally enhanced wiring board and the semiconductor assembly using the same according to the present invention have numerous advantages. The wiring board and the semiconductor assembly are reliable, inexpensive and well-suited for high volume manufacture. The thermal conduction pathway can be provided by the metal slug and conductive vias of the build-up circuitry. The metal pillar can provide power delivery and return paths when interconnected with build-up circuitry and can minimize the voltage drop. The signal routing provided by the build-up circuitry is advantageous for high I/O and high performance applications due to the high routing capability of the build-up circuitry. The patterned interconnect substrate can provide mechanical support and signal routing. The thermally enhanced wiring board and the semiconductor assembly using the same are reliable, inexpensive and well-suited for high volume manufacture.

The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional packaging techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

Various changes and modifications to the embodiments described herein will be apparent to those skilled in the art. For instance, the materials, dimensions, shapes, sizes, steps and arrangement of steps described above are merely exemplary. Such changes, modifications and equivalents may be made without departing from the spirit and scope of the present invention as defined in the appended claims.

Although the present invention has been explained in relation to its preferred embodiment, it is to be understood that many other possible modifications and variations can be made without departing from the spirit and scope of the invention as hereinafter claimed.

What is claimed is:

1. A thermally enhanced wiring board with thermal pad and electrical post, comprising:
a patterned interconnect substrate that includes first and second apertures;
a metal slug that serves as the thermal pad and extends into the first aperture of the patterned interconnect substrate;
a metal pillar that serves as the electrical post and extends into the second aperture of the patterned interconnect substrate;
an adhesive that covers the patterned interconnect substrate in a first vertical direction, extends into gaps between the metal slug and the patterned interconnect substrate and between the metal pillar and the patterned interconnect substrate in a second vertical direction opposite the first vertical direction;
a build-up circuitry that covers the metal slug, the metal pillar and the adhesive in the first vertical direction and includes a first dielectric layer, first via openings, and a first conductive trace, wherein the first via openings in the first dielectric layer are aligned with the metal slug and the metal pillar, and the first conductive trace extends from the first dielectric layer in the first vertical direction and extends through the first via openings in the second vertical direction and directly contacts the metal slug and the metal pillar respectively; and
a plated through hole that extends through the adhesive and provides an electrical connection between the patterned interconnect substrate and the build-up circuitry.

2. The thermally enhanced wiring board with thermal pad and electrical post of claim 1, wherein the thermal pad and the electrical post are substantially coplanar with the patterned interconnect substrate in the second vertical direction and are coplanar with the adhesive in the first vertical direction.

3. The thermally enhanced wiring board with thermal pad and electrical post of claim 1, wherein a surface of the thermal pad is exposed from the second vertical direction for semiconductor chip attachment.

4. The thermally enhanced wiring board with thermal pad and electrical post of claim 1, further comprising a patterned metal layer that extends from the adhesive in the second vertical direction and electrically couples the thermal pad and the patterned interconnect substrate and the electrical post and the patterned interconnect substrate respectively.

5. The thermally enhanced wiring board with thermal pad and electrical post of claim 4, wherein the patterned metal layer is coplanar with the patterned interconnect substrate, the thermal pad and the electrical post in the second vertical direction.

6. A thermally enhanced wiring board with thermal pad and electrical post, comprising:
a patterned interconnect substrate that includes first and second apertures;
a metal slug that serves as the thermal pad and extends into the first aperture of the patterned interconnect substrate;
a metal pillar that serves as the electrical post and extends into the second aperture of the patterned interconnect substrate;
an adhesive that covers the patterned interconnect substrate in a first vertical direction, extends into gaps between the metal slug and the patterned interconnect substrate and between the metal pillar and the patterned interconnect substrate in a second vertical direction opposite the first vertical direction; and
a build-up circuitry that covers the metal slug, the metal pillar and the adhesive in the first vertical direction and includes a first dielectric layer, first via openings, an additional first via opening and a first conductive trace, wherein the first via openings in the first dielectric layer are aligned with the metal slug and the metal pillar, the additional first via opening extends through the first dielectric layer and the adhesive and is aligned with the patterned interconnect substrate, and the first conductive trace extends from the first dielectric layer in the first vertical direction and extends through the first via openings and the additional first via opening in the second vertical direction and directly contacts the metal slug, the metal pillar and the patterned interconnect substrate respectively.

7. The thermally enhanced wiring board with thermal pad and electrical post of claim 6, further comprising a plated through hole that extends through the adhesive and provides an electrical connection between the patterned interconnect substrate and the build-up circuitry.
